(19) United States
(12) Patent Application Publication
(10) Pub. No.: US 2007/0184577 A1
(43) Pub. Date: Aug. 9, 2007

(54) Method of fabricating wafer level package

(75) Inventors: Hyun-Soo Chung, Hwaseong-si (KR); Seong-Deok Hwang, Seoul (KR); Seung-Kwan Ryu, Yongin-si (KR); Dong-Ho Lee, Seongnam-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/653,862

(22) Filed: Jan. 17, 2007

(30) Foreign Application Priority Data
Feb. 7, 2006 (KR) 10-2006-0011774

(51) Int. Cl. H01L 21/00

(52) U.S. Cl. 438/106

(57) ABSTRACT

A method of fabricating a wafer level package may include providing semiconductor substrate having a bonding pad; forming a passivation layer on the semiconductor substrate and partially exposing the boding pad, forming a first insulating layer on the passivation layer; forming a seed metal layer on the first insulating layer and the bond pad; forming a metal bump on a portion of the seed metal layer; forming a redistributing metal layer on the seed metal layer by melting the metal bump; forming a second insulating layer on the first insulating layer and the redistributing metal layer to expose a metal pad; and forming a conductive bump on the exposed metal pad.

### PRIORITY STATEMENT

This U.S. non-provisional application claims the benefit of priority under 35 U.S.C. §119 from Korean Patent Application No. 10-2006-0011774, filed on Feb. 7, 2006 in the Korean Intellectual Property Office (KIPO), the disclosure of which is incorporated herein in its entirety by reference.

### BACKGROUND

1. Field

Example embodiments relate to a method of fabricating a wafer level package, for example, a method of fabricating a wafer level package by melting metal to form a redistributing metal layer in a highly-integrated device.

2. Description of the Related Art

Electronic products may utilize semiconductor packages including integrated circuit chips. It may be desired and/or required that electronic products be smaller and lighter, and thus semiconductor packages may be designed to be smaller and lighter. Semiconductor packages that may be smaller in size and lighter in weight may include, for example, flip chips, wafer level packages, board on chips (BOC's), and the like.

FIG. 1 is a sectional view of a conventional wafer level package 101. Referring to FIG. 1, the conventional wafer level package 101 may include a semiconductor substrate 111, a bonding pad 121, a passivation layer 131, a first interlayer insulating layer 141, a second interlayer insulating layer 142, a seed metal layer 151, a redistributing metal layer 161, and/or a conductive bump 171.

A method for manufacturing a conventional wafer level package 101 may include a plating method to form the redistributing metal layer 161. For example, metal material may be formed on the seed metal layer 151 using the seed metal layer 151 as a plating electrode. The plating method may take longer amount of time to form the redistributing metal layer 161. If it takes longer to form the redistributing metal layer 161, it may take a longer time to manufacture the wafer level package 101, and thus the productivity in fabricating the wafer level package 101 may be reduced.

FIG. 2 is a sectional view of the conventional wafer level package 101 of FIG. 1 showing that the seed metal layer 151 of the wafer level package 101 may be excessively etched. In general, the metals used to form the seed metal layer 151 and the redistributing metal layer 161 may be the same or similar to each other. Thus, if a portion of the redistributing metal layer 161 is etched, the seed metal layer 151 formed below the redistributing metal layer 161 may be etched by isotropic etching. For example, a portion 181 of the seed metal layer 151 may be etched excessively as shown in FIG. 2. Thus, the structure of the redistributing metal layer 161 may becomes weaker. If the structure of the redistributing metal layer 161 is weaker, it may affect the signal transfer characteristics of the wafer level package 101.

### SUMMARY

Example embodiments provide a method of fabricating a wafer level package capable of shortening the time required in the fabrication.

Example embodiments provide a method of fabricating a wafer level package capable of preventing and/or reducing excessive etching of a seed metal layer formed below a redistributing metal layer.

In an example embodiment, a method of fabricating a semiconductor level package may include providing a semiconductor substrate having a bonding pad; forming a passivation layer on the semiconductor substrate and partially exposing the bonding pad; forming a first insulating layer on the passivation layer; forming a seed metal layer on the first insulating layer and the boding pad; forming a metal bump on a portion of the seed metal layer; forming a redistributing metal layer on the seed metal layer by melting the metal bump; forming a second insulating layer on the first insulating layer and the redistributing metal layer to expose a metal pad; and forming a conductive bump on the exposed metal pad.

According to an example embodiment, forming the first insulating layer on the passivation layer may include forming a first insulating layer on the bonding pad and an entire surface of the passivation layer; forming a photoresist layer on the first insulating layer; removing the photoresist layer on the bonding pad; removing the insulating layer on the bonding pad; and removing the photoresist layer remaining on the first insulating layer.

According to an example embodiment, forming the seed metal layer on the semiconductor substrate may include forming the seed metal layer on the bonding pad and an entire surface of the passivation layer.

According to an example embodiment, the method may further include forming a photoresist layer on the semiconductor substrate may include forming a photoresist layer on an entire surface of the seed metal layer; removing a portion of the photoresist layer to expose a portion of the seed metal layer on which the redistributing metal layer may be formed. Forming the metal bump on a portion of the seed metal layer may include forming the metal bump on the exposed portion of the seed metal layer that is formed on the bonding pad. Forming the redistributing metal layer on the seed metal layer by melting the metal bump may include forming the redistributing metal layer on the exposed portion of the seed metal layer.

According to an example embodiment, the method may further include removing the photoresist layer remaining on the seed metal layer to expose a portion of the seed metal layer; and removing the exposed portion of the seed metal layer.

According to an example embodiment, forming the redistributing metal layer on the exposed seed metal layer by melting the metal bump may include melting the metal bump by increasing a temperature of the metal bump.

According to an example embodiment, forming the redistributing metal layer on the exposed seed metal layer by melting the metal bump may include melting the metal bump by increasing an ambient temperature around the metal bump.

According to an example embodiment, forming the second insulating layer on the first insulating layer and the redistributing metal layer to expose a metal pad may include forming the second insulating layer on the entire surface of the seed metal layer and the first insulating layer; forming a photoresist layer on the second insulating layer; removing a portion of the photoresist layer on the metal pad; removing a portion of the second insulating layer on the metal pad; and removing the photoresist layer remaining on the second insulating layer.

According to an example embodiment, forming a first insulating layer on the passivation layer on the passivation layer may include forming a first insulating layer on the bonding pad and an entire surface of the passivation layer; forming a photoresist layer on the first insulating layer; removing a portion of the photoresist layer on the bonding pad; removing a portion of the insulating layer on the bonding pad; and removing the photoresist layer remaining on the first insulating layer.

According to an example embodiment, forming a seed metal layer on the passivation layer and boding pad may include forming a seed metal layer on the bonding pad and an entire surface of the passivation layer; forming a photoresist layer on an entire surface of the seed metal layer; removing a portion of the photoresist layer to expose a portion of the seed metal layer other than where the redistributing metal layer may be formed; etching the exposed seed metal layer; and removing the photoresist layer remaining on the seed metal layer.

According to an example embodiment, forming the metal bump on a portion of the seed metal layer may include forming the metal bump on a portion of seed metal layer that is formed on the bonding pad.

According to an example embodiment, forming the metal bump on a portion of the seed metal layer may include forming the metal bump on a portion of the seed metal layer that is formed on the bonding pad.

According to an example embodiment, the method may further include removing a portion of the second insulating layer to expose a metal pad.

According to an example embodiment, removing a portion of the second insulating layer to expose a metal pad may include forming a photoresist layer on the second insulating layer; removing a portion of the photoresist layer where the metal pad may exposed; removing the second insulating layer on the metal pad to expose the metal pad; and removing the photoresist layer remaining on the second insulating layer.

According to an example embodiment, the conductive bump may be composed of solder.

According to an example embodiment, a plurality of the bonding pads and a plurality of the conductive bumps may be formed.

### BRIEF DESCRIPTION OF THE DRAWINGS

Example embodiments will be described with reference to the accompanying drawings.

FIG. 1 is a sectional view of a conventional wafer level package.

FIG. 2 is a sectional view of a conventional wafer level package showing that a seed metal layer of the wafer level package may be excessively etched.

FIG. 3 is a sectional view of a wafer level package according to an example embodiment.

FIGS. 4 through 11 are sectional views of a method of fabricating a wafer level package according to an example embodiment.

FIGS. 12 through 16 are sectional views of a method of fabricating a wafer level package according to an example embodiment.

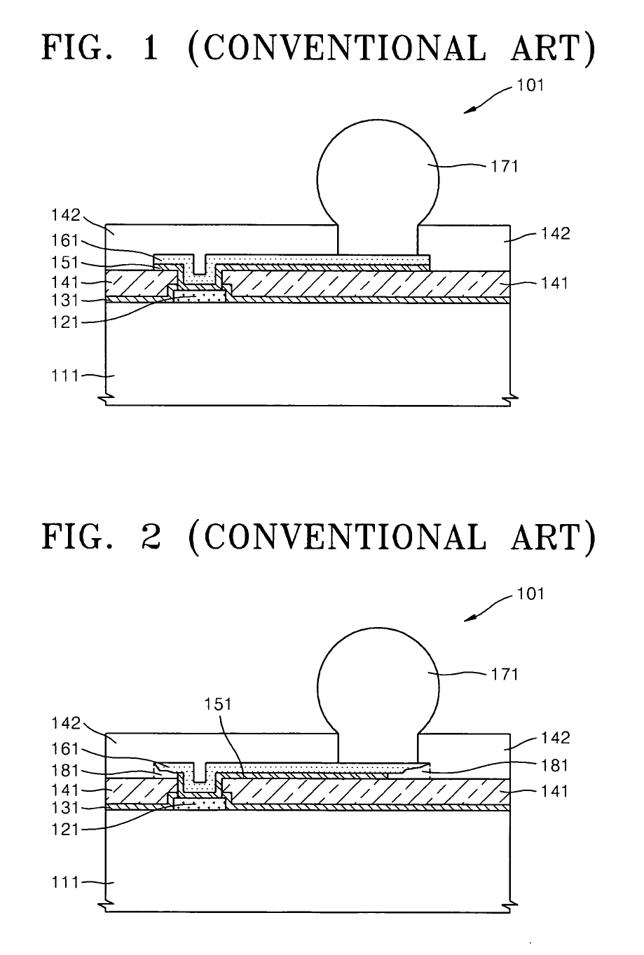

### DESCRIPTION OF EXAMPLE EMBODIMENTS

Example embodiments will now be described more fully hereinafter with reference to the accompanying drawings, in which example embodiments are shown. In the drawings, like numbers refer to like elements throughout the specification. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below.” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

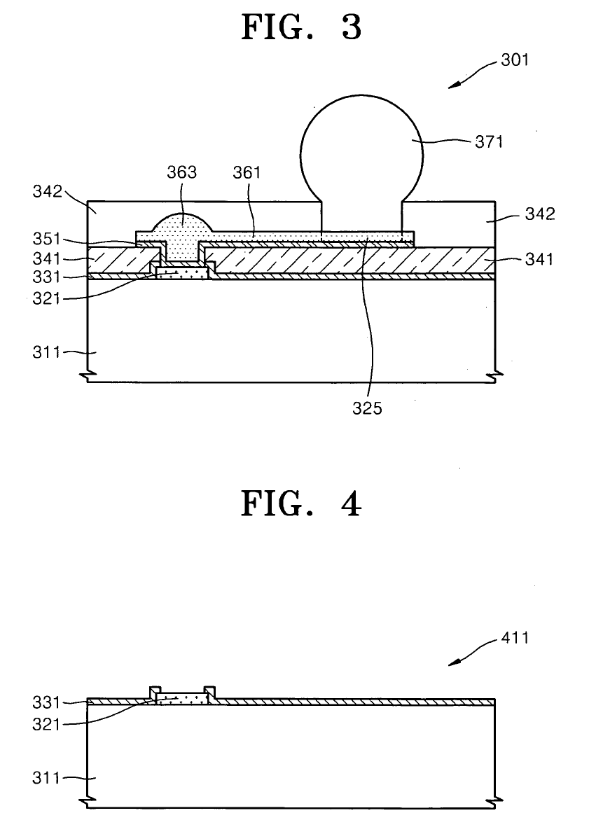

FIG. 3 is a sectional view of a wafer level package according to an example embodiment.

Referring to FIG. 3, a wafer level package 301 may include a semiconductor substrate 311, a bonding pad 321, a passivation layer 331, a first insulating layer 341, a second insulating layer 342, a seed metal layer 351, a redistributing metal layer 361, a metal pad 325, and/or a conductive bump 371.

The redistributing metal layer 361 may be formed by melting a metal bump 363 formed on the bonding pad 321, thus the time required to form the redistributing metal layer 361 may be shortened. Further, because the redistributing metal layer 361 may not be etched, the seed metal layer 351 formed below the redistributing metal layer 361 may not excessively etched.

FIGS. 4 through 11 are sectional views of a method of fabricating a wafer level package according to an example embodiment.

Referring to FIG. 4, an integrated circuit device 411 may include semiconductor substrate 311, a bonding pad 321 formed on the semiconductor substrate 311, and a passivation layer 331 formed on the semiconductor substrate 311 exposing or partially exposing the bonding pad 321. A plurality of semiconductor elements (not shown) may be formed on the semiconductor substrate 311. The bonding pad 321 may be electrically connected to at least one of the plurality of semiconductor elements. For example, the bonding pad 321 may be composed of a metal, for example, aluminum, and may function as an input/output terminal for an electrical signal. For example, the passivation layer 331 may be composed of an insulating material, for example, silicon oxide or silicon nitride, and may protect the plurality of semiconductor elements from the external environment. The passivation layer 331 may be formed on an edge of the bonding pad 321, and may protect the bonding pad 321.

According to an example embodiment of the integrated circuit device 411 as shown in FIG. 4, the semiconductor substrate 311 may include one bonding pad 321. However, an example embodiment may include a plurality of bonding pads 321 formed on the semiconductor substrate 311. The integrated circuit device 411 may be complete in this first fabrication state, and may be packaged in this state and used in electronic products. A plurality of the integrated circuit devices 411 may be formed from one wafer.

Referring to FIG. 5, a first insulating layer 341 may be formed on the passivation layer 331. The first insulating layer 341 may function as a buffer against thermal stress. For example, the first insulating layer 341 may be composed of polyimide, polybenzoxazole (PBO), benzocyclobutene (BCB), epoxy, polymer, or the like.

A method of forming the first insulating layer 341 may include forming a first insulating layer 341 on the entire surface of the semiconductor substrate 311. For example, the first insulating layer 341 may be formed using a spin coating method or a deposition method. A photoresist layer (not shown) may be formed on the first insulating layer 341. The photoresist layer may be patterned to remove a portion of the photoresist layer formed on the bonding pad 321. A portion of the first insulating layer 341 formed on the bonding pad 321 may be etched and removed using an etch process. The photoresist layer remaining on the first insulating layer 341 may be removed.

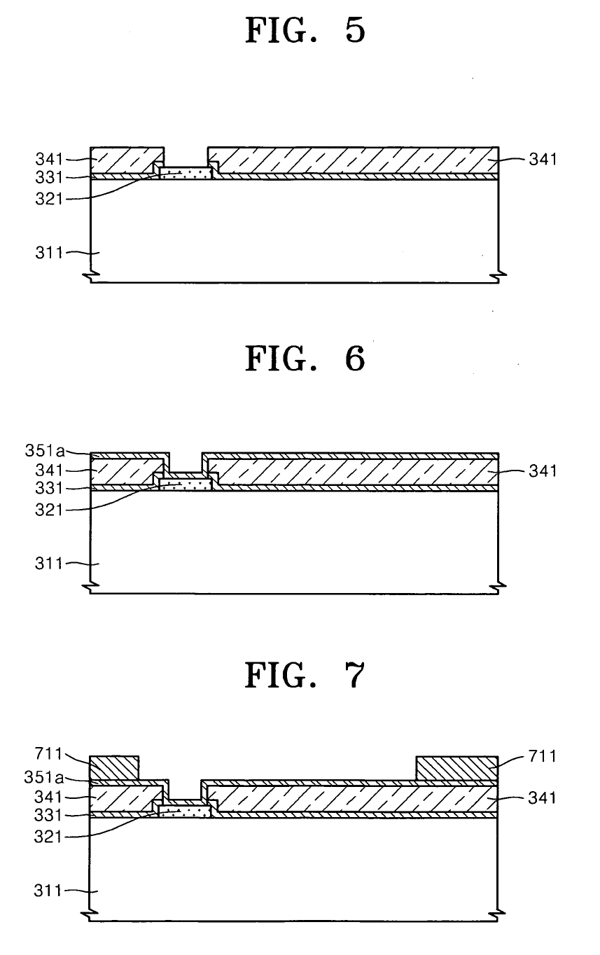

Referring to FIG. 6, a seed metal layer 351a may be formed on the entire surface of the bonding pad 321 and an entire surface of the first insulating layer 341. The seed metal layer 351a may improve an adhesive strength of the redistributing metal layer 361. For example, the seed metal layer 351a may be composed of titanium, chrome, copper, nickel, or an alloy thereof, and may be formed using a sputtering method or an evaporation method.

Referring to FIG. 7, a photoresist layer 711 may be formed on the seed metal layer 351a and may expose a portion of the seed metal layer 351a where the redistributing metal layer 361 may be formed. For example, the photoresist layer 711 may be formed on the entire surface of the seed metal layer 351a, and the photoresist layer 711 may be patterned to remove a portion of the photoresist layer 711 in which the redistributing metal layer 361 may be formed.

Referring to FIG. 8, a metal bump 811 may be formed on a portion of the exposed portion of the seed metal layer 351 where the photoresist layer may have been removed. For example, the metal bump 811 may be formed on a portion of seed metal layer 351 formed on the bonding pad 321. For example, the metal bump 811 may be composed of solder. For example, the metal bump may be composed of a material that may be different from the material of the seed metal layer 351 and that may have a good conductivity.

Because the metal bump 811 may be composed of a material different from the material of the seed metal layer 351, a portion of the seed metal layer 351 that may be formed below the redistributing metal layer 361 may not be etched during the process of etching the seed metal layer 351.

Referring to FIG. 9, a metal line 361 may be formed on the exposed seed metal layer 351 by melting the metal bump 811. The metal material may spread on the exposed seed metal layer 351 and may be cooled to form the redistributing metal layer 361. For example, a temperature of the semiconductor substrate 311 and/or an ambient temperature around the semiconductor substrate 311 may be increased to melt the metal bump 811 until the material of the metal bump 811 is melted. The melted metal may spread over the portion of the seed metal layer 351 in which the photoresist layer 711 may not be formed and may be cooled to form the redistributing metal layer 361.

Because the redistributing metal layer 361 may be formed by melting the metal bump 811, the time needed to form the redistributing metal layer 361 may be reduced. For example, it may take about 40 minutes to 1 hour to form the redistributing metal layer 361 using a plating method, but it may take about 10 minutes to form the redistributing metal layer 361 by melting the metal bump 811.

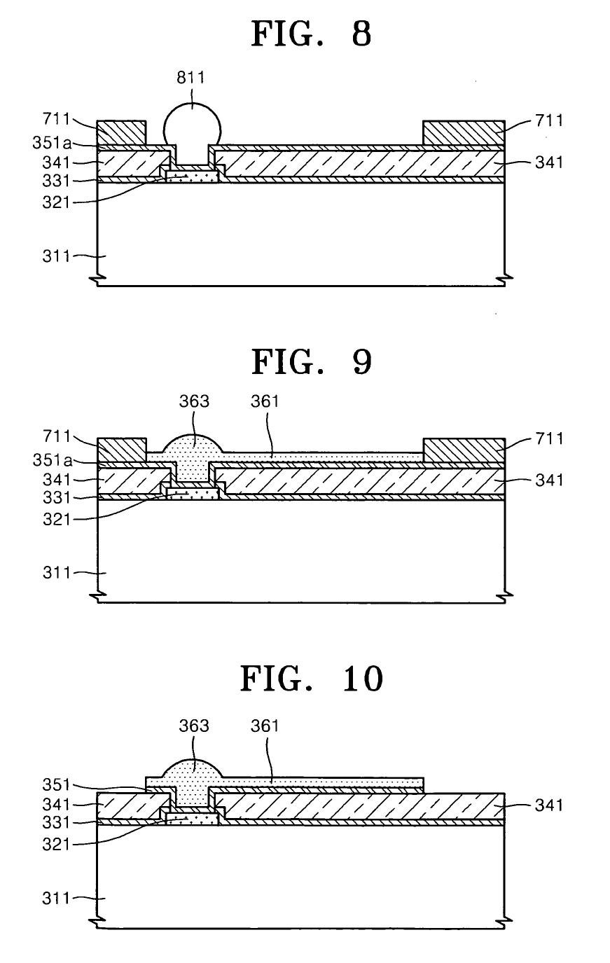

Referring to FIG. 10, a portion of the seed metal layer 351a exposed when the photoresist layer 711 is removed may be etched by an etch process and may be removed. For example, the seed metal layer 351a formed from an edge of the redistributing metal layer 361 to an edge of the semiconductor substrate 311 may be removed. For example, to remove the seed metal layer 351a formed below the photoresist layer 711, the photoresist layer 711 may be removed, a photoresist layer (not shown) may be formed on the redistributing metal layer 361, the seed metal layer 351 may be etched, and the photoresist layer on the redistributing metal layer 361 may be removed.

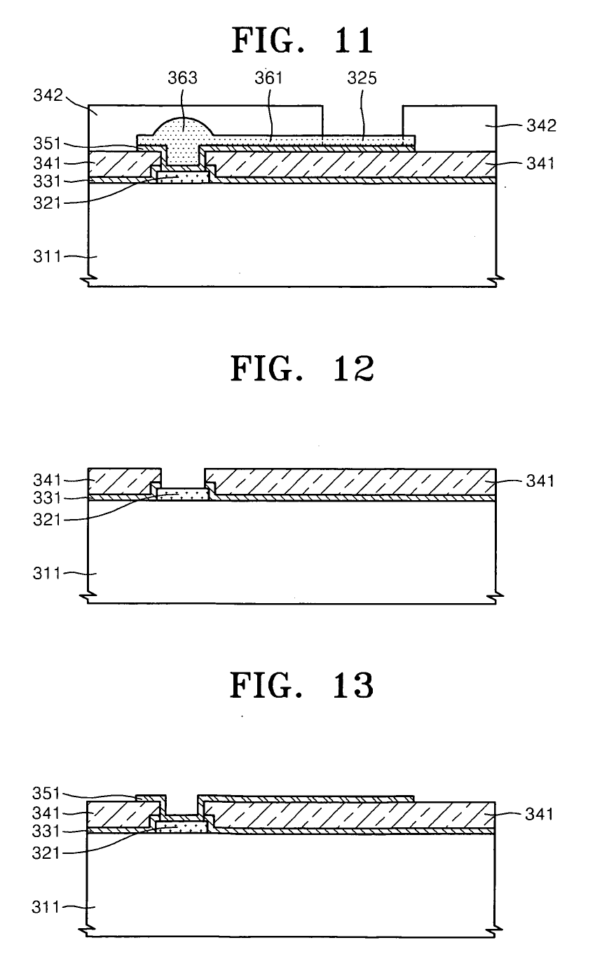

Referring to FIG. 11, a second insulating layer 342 may be formed on the first insulating layer 341 and the redistributing metal layer 361 and may expose a portion of the metal layer to form a metal pad 325. For example, the second insulating layer 342 may be composed of a material identical or similar to that of the first insulating layer 341.

A method of forming the second insulating layer 342 may include forming a second insulating layer 342 on the entire surface of the first insulating layer 341 and the redistributing metal layer 361. For example, the second insulating layer 342 may be formed using a spin coating method or a deposition method. A photoresist layer (not shown) may be formed on the second insulating layer 342. A portion of the photoresist layer may be removed to expose a portion of the second insulating layer 342. A portion of the second insulating layer 342 may be removed using an etch process to expose a metal pad 325. The photoresist layer that may remain on the second insulating layer 342 may be removed.

Referring again to FIG. 3, a conductive bump 371 may be formed on the metal pad 325 to complete the formation of the wafer level package 301. For example, the conductive bump 371 may be composed of solder. For example, the conductive bump 371 may be composed of a material having a good conductivity, for example, lead (Pb) or a tin-lead alloy (Sn—Pb). If the conductive bump 371 is joined with an external instrument (not shown), the wafer level package 301 may send and receive electric signals with the external instrument. According to an example embodiment as shown in FIG. 3, the wafer level package 301 may include one conductive bump 371. However, an example embodiment of the wafer level package 301 may include a plurality of the conductive bumps 371.

FIGS. 12 through 16 are sectional views of a method of fabricating the wafer level package according to an example embodiment.

Referring to FIG. 12, a bonding pad 321 may be formed on a semiconductor substrate 311, and a passivation layer 331 may be formed on the semiconductor substrate 311 that may expose or partially expose the bonding pad 321. The structure of the semiconductor substrate 311, the bonding pad 321, and the passivation layer 331 may be the same as the structure of the integrated circuit device 411 as illustrated in FIG. 4. A plurality of semiconductor elements (not shown) may be formed on the semiconductor substrate 311 and the bonding pad 321 may be electrically connected to at least one of the plurality of semiconductor elements. For example, the bonding pad 321 may be composed of metal, for example, aluminum, and may function as an input/output terminal for an electrical signal and. For example, the passivation layer 331 may be composed of an insulating material, for example, silicon oxide or silicon nitride, and may protect the plurality of semiconductor elements from the external environment. The passivation layer 331 may be formed on an edge of the bonding pad 321, and may protect the bonding pad 321.

A first insulating layer 341 may be formed on the passivation layer 331. The first insulating layer 341 may function as a buffer against thermal stress. For example, the first insulating layer 341 may be composed of polyimide, polybenzoxazole (PBO), benzocyclobutene (BCB), epoxy, polymer, or the like.

A method of forming the first insulating layer 341 may include forming a first insulating layer 341 on the entire surface of the semiconductor substrate 311. For example, the first insulating layer 341 may be formed using a spin coating method or a deposition method. A photoresist layer (not shown) may be formed on the first insulating layer 341. The photoresist layer may be patterned to remove a portion of the photoresist layer formed on the bonding pad 321. A portion of the first insulating layer 341 formed on the bonding pad 321 may be etched and removed using an etch process. The photoresist layer remaining on the first insulating layer 341 may be removed.

Referring to FIG. 13, a seed metal layer 351 may be formed at a position where the redistributing metal layer 361 will be formed. The seed metal layer 351 may improve an adhesive strength of the redistributing metal layer 361. For example, the seed metal layer 351 may be composed of titanium, chrome, copper, nickel, or an alloy thereof, and may be formed using a sputtering method or a deposition method.

A method of forming the seed metal layer 351 may include forming a seed metal layer 351 on the bonding pad 321 and an entire surface of the first insulating layer 341. A photoresist layer (not shown) may be formed on the seed metal layer 351. The photoresist layer may be patterned to remove a portion of the photoresist layer to expose a portion of the seed metal layer 351 on which the redistributing metal layer 361 may be formed. The exposed portion of the seed metal layer 351 may be etched using an etch process. The photoresist layer that may remain on the seed metal layer 351 may be removed. Thus, the seed metal layer 351 may be formed.

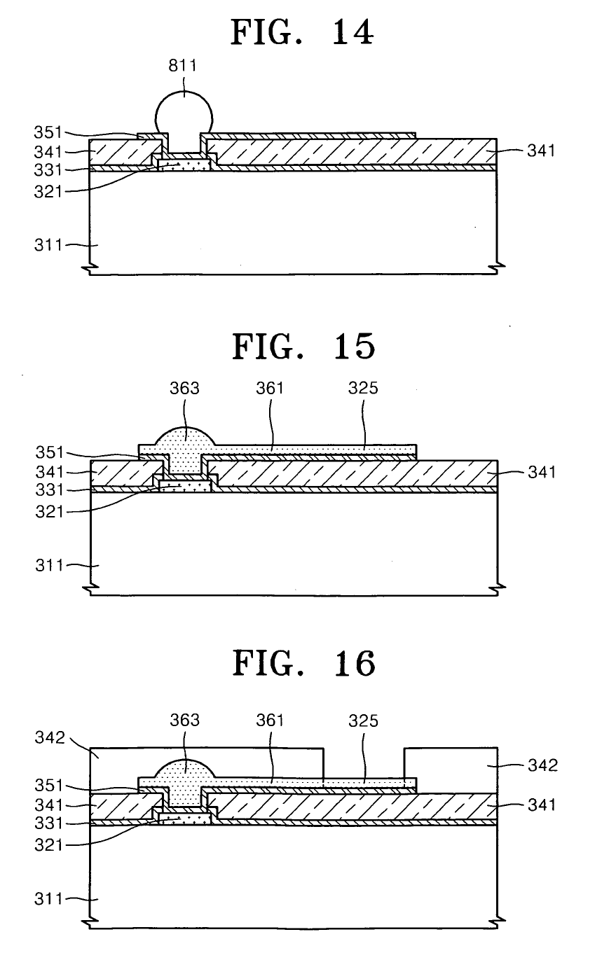

Referring to FIG. 14, a metal bump 811 may be formed on a portion of the seed metal layer 351. The metal bump 811 may be formed on a portion of the seed metal layer 351 over the bonding pad 321. For example, the metal bump 811 may be composed of solder. For example, the metal bump 811 may be composed of a material that may be different from that the material of the seed metal layer 351 and that may have a good conductivity.

Because the metal bump 811 may be composed of a different material from the material of the seed metal layer 351, the seed metal layer 351 formed below the redistributing metal layer 361 may not be etched during the process of etching the seed metal layer 351.

Referring to FIG. 15, a redistributing metal layer 361 may be formed on the seed metal layer 351 by melting the metal bump 811. Because the metal material of the metal bump 811 may an adhesive effect on the metal material of the seed metal layer 351, the metal material of the metal bump 811 may only run over the seed metal layer 351. The metal material may be cooled to form the redistributing metal layer 361. Thus, the redistributing metal layer 361 is formed only on the seed metal layer 351.

For example, a temperature of the semiconductor substrate 311 and/or an ambient temperature around the semiconductor substrate 311 may be increased in order to melt the metal bump 811 until the material of the metal bump 811 is melted. The melted metal may spread over the seed metal layer 351 and may be cooled to form the redistributing metal layer 361.

Because the redistributing metal layer 361 may be formed by melting the metal bump 811, the time needed to form the redistributing metal layer 361 may be reduced. For example, it may take about 40 minutes to 1 hour to form the redistributing metal layer 361 using a plating method, but it may takes about 10 minutes to form the redistributing metal layer 361 by melting the metal bump 811.

Referring to FIG. 16, a second insulating layer 342 may be formed on the first insulating layer 341 and the redistributing metal layer 361 and may expose a portion of the redistributing metal layer 361 to form a metal pad 325. For example, the second insulating layer 342 may be composed of a material identical to or similar to that of the first insulating layer 341.

A method of forming the second insulating layer 342 may include forming an insulating layer on the entire surface of the first insulating layer 341 and the redistributing metal layer 361. A photoresist layer (not shown) may be formed on the second insulating layer 342. The photoresist layer may be patterned to remove a portion of the photoresist layer and may expose a portion of the second insulating layer 342. The exposed portion of the second insulating layer 342 may be removed to expose a metal pad 325.

Referring again to FIG. 3, a conductive bump 371 may be formed on the metal pad 325 to complete the fabrication of the wafer level package 301. For example, the conductive bump 371 may be composed of solder. A plurality of the conductive bumps 371 may be formed in the wafer level package 301.

As described above, according to example embodiments, the time needed to form the redistributing metal layer 361 is significantly reduced by forming the metal bump 811 on the seed metal layer 351, and melting the metal bump 811. Therefore, a productivity of the wafer level package 301 is improved.

During fabrication of the wafer level package 301, because the redistributing metal layer 361 may not etched, the seed metal layer 351 below the redistributing metal layer 361 may not be excessively etched. Thus, the structure of the redistributing metal layer 361 may not be damaged, and accordingly signal transfer characteristics of the wafer level package 301 may not be negatively affected.

While the example embodiments have been particularly shown and described, it will be understood by those of ordinary skill in the art that various changes in form and details may be made therein without departing from the spirit and scope as defined by the following claims.

What is claimed is:

1. A method of fabricating a semiconductor level package, the method comprising:
providing a semiconductor substrate having a bonding pad;
forming a passivation layer on the semiconductor substrate and partially exposing the bonding pad;
forming a first insulating layer on the passivation layer;
forming a seed metal layer on the first insulating layer and the bonding pad;
forming a metal bump on a portion of the seed metal layer;
forming a redistributing metal layer on the seed metal layer by melting the metal bump;
forming a second insulating layer on the first insulating layer and the redistributing metal layer to expose a metal pad; and
forming a conductive bump on the exposed metal pad.

2. The method of claim 1, wherein forming the first insulating layer on the passivation layer includes:
forming the first insulating layer on the bonding pad and an entire surface of the passivation layer;
forming a photoresist layer on the first insulating layer;
removing a portion of the photoresist layer on the bonding pad;
removing a portion of the first insulating layer on the bonding pad; and
removing the photoresist layer remaining on the first insulating layer.

3. The method of claim 1, wherein forming the seed metal layer on first insulating layer and the bonding pad includes forming the seed metal layer on the bonding pad and an entire surface of the passivation layer.

4. The method of claim 3, further comprising:
forming a photoresist layer on an entire surface of the seed metal layer; and
removing a portion of the photoresist layer to expose a portion of the seed metal layer on which the redistributing metal layer is to be formed,
wherein forming the metal bump on a portion of the seed metal layer includes forming the metal bump on the exposed portion of the seed metal layer that is formed on the bonding pad, and forming the redistributing metal layer on the seed metal layer by melting the metal bump includes forming the redistributing metal layer on the exposed portion of the seed metal layer.

5. The method of claim 4, further comprising:
removing the photoresist layer remaining on the seed metal layer to expose a portion of the seed metal layer; and
removing the exposed portion of the seed metal layer.

6. The method of claim 5, wherein removing the exposed portion of the seed metal layer includes:
forming a photoresist layer on the redistributing metal layer;
etching the exposed portion of the seed metal layer; and
removing the photoresist layer on the redistributing metal layer.

7. The method of claim 1, wherein forming the redistributing metal layer on the seed metal layer by melting the metal bump includes melting the metal bump by increasing a temperature of the metal bump.

8. The method of claim 7, wherein the temperature of the metal bump is increased by increasing an ambient temperature around the metal bump.

9. The method of claim 7, wherein the temperature of the metal bump is increased by increasing a temperature of the semiconductor substrate.

10. The method of claim 1, wherein forming the second insulating layer on the first insulating layer and the redistributing metal layer to expose a metal pad includes:
forming the second insulating layer on the entire surface of the seed metal layer and the first insulating layer;
forming a photoresist layer on the second insulating layer;
removing a portion of the photoresist layer to expose a portion of the second insulating layer;
removing a portion of the second insulating layer to expose the metal pad; and
removing the photoresist layer remaining on the second insulating layer.

11. The method of claim 1, wherein forming the seed metal layer on the first insulating layer and the bonding pad includes:
forming the seed metal layer on the bonding pad and an entire surface of the passivation layer;
forming a photoresist layer on an entire surface of the seed metal layer;
removing a portion of the photoresist layer to expose a portion of the seed metal layer other than where the redistributing metal layer is to be formed;
etching the exposed seed metal layer; and
removing the photoresist layer remaining on the seed metal layer.

12. The method of claim 1, wherein forming the metal bump on a portion of the seed metal layer includes forming the metal bump on a portion of the seed metal layer that is formed on the bonding pad.

13. The method of claim 1, wherein the conductive bump is composed of solder.

14. The method of claim 1, wherein a plurality of the bonding pads and a plurality of the conductive bumps are formed.
